(19) United States
(12) Patent Application Publication
(10) Pub. No.: US 2010/0200041 A1
(43) Pub. Date: Aug. 12, 2010

(54) Modular solar photovoltaic canopy system for development of rail vehicle traction power

(76) Inventor: David Dayton Dearborn, San Jose, CA (US)

Correspondence Address: David D. Dearborn, 1408 Hotspur Ct., San Jose, CA, 95125, US

(21) Appl. No.: 12/584,670

(22) Filed: Sep. 10, 2009

Related U.S. Application Data
(60) Provisional application No. 61/192,871, filed on Sep. 23, 2008.

(51) Int. Cl. H01L 31/042

(52) U.S. Cl. 136/244

(57) ABSTRACT

This invention provides a method by which rail systems can use air space above tracks and right of way for generating traction power for electric powered rail vehicles. Through the design and installation of rail-specific solar photovoltaic canopy modules, replicated and joined together in assemblies of various lengths, transit districts, rail agencies and operators can develop energy for rail vehicle traction power. Integrating solar PV technology and the supply and distribution of traction power can provide a rail system increased levels of energy independence, lower fixed energy cost over 25 to 30 years and the possibility of providing Carbon Neutral rail service.

This application claims priority from U.S. provisional patent application No. 61/192,871 filed Sep. 23, 2008.

### TECHNICAL FIELD

The present invention relates to the field of land motor vehicles where said motor(s) is supplied with power from an external source, and that source of power is derived from the sun, a freely occurring natural force.

### BACKGROUND

The present invention provides a means by which rail (railroad) transportation operators can generate megawatts of carbon free electrical power from the space over rail tracks and right-of-way without buying or leasing significant amounts of sun accessible space or power transmission right of way.

Public rail transportation is becoming increasingly important in the effort to lower carbon emissions from automobile usage. Public rail transportation is migrating from diesel electric locomotive to electric module unit (EMU) vehicles as they operate more efficiently, create less noise and are less dependant on carbon based energy.

Electrified rail systems depends on large quantities of electric power, much of which is derived from coal, natural gas or carbon based energy sources generating tens of thousands of tons of carbon dioxide and other green house gases (GHG).

Periods of hot weather or peak electrical demand strain electrical producing capacities or cause reductions in service. Population growth and increasing urban densification will require more power generation plants, typically dependant on carbon based sources of energy. U.S. Department of Energy projections state that carbon free renewable energy generating plants such as wind, solar, nuclear or other will not come on line fast enough to meet this growing demand.

The U.S. Department of Energy (DOE) regulates the generation and distribution of electrical power. The U.S. Department of Transportation (DOT) and the Federal Railroad Administration (FRA) regulate rail and public rail transportation. The current body of regulations and assumptions of these and State level regulations do not address or expressly permit the concept embodied in the preferred invention.

Global warming, the rising cost of carbon based energy, rapid advances in solar PV technology and large scale automated manufacturing are rapidly changing the way we view energy, transportation and the way we live. Research, analysis and design work embodied herein relate directly to these recent developments.

### BRIEF SUMMARY OF THE INVENTION

A system of solar PV canopy modules positioned over rail tracks can provide a method by which rail system operators can become Carbon Neutral, or make some portions of those systems Carbon Neutral; and in the process, offer rail operators an increased level of control over their carbon footprint and cost of traction power.

Just as no one or two of the developments noted above (see background) make the case for favoring this invention; no single or pair of benefits make the case favoring modular solar PV canopy over rail power generation systems. The combination of changing environmental conditions and social values together with various benefits of this invention provide the foundation for its considerations and deployment.

Example of one benefit: Energy production from an urban or regional solar PV canopy over rail right of way during periods of peak demand coincides with the canopy's periods of peak power output. During periods of peak demand, a carbon neutral modular solar PV canopy system over railroad tracks or right of way can produce 40% to 50% more electrical power than required for traction power of said rail vehicles. This surplus energy going into the local grid will reduce the need for carbon based peak generating plants and the probability of reduced electrical supply service levels.

This invention and the long term fixed cost of energy (levelized cost of energy (LCOE)) offered by same would allow an electrified rail system to;

a) become Carbon Neutral faster than the local power grid supplier,

b) assist the local power grid supplier in reducing its carbon footprint,

c) fix its average annual cost of rail traction power for 25 to 30 years,

d) insulate itself from uncontrolled market driven pricing variations of carbon based energy,

e) produce local jobs in design, construction, installation and maintenance in a clean and sustainable technology,

f) and make a greater contribution to a nation's energy independence.

### BRIEF DESCRIPTION OF THE DRAWINGS

The explanation of the present invention can be understood by considering the following description in conjunction with the accompanying drawings in which:

FIG. 1 illustrates a view from above of the preferred embodiment. In this view, solar photovoltaic panels (4) cover the supporting structure(s) (3) below (hidden in this view). In this view three solar PV canopy modules (1-1) are shown as joined end to end (21). Each of the three canopy modules in this view have a similar number of solar PV panels (4) on each side (2) of the vertical supporting member and structure (3), and the vertical support member of the structure (3) is centered between ends of each module or section.

FIG. 2 shows an end view or cross-section view of one canopy module (1-1) illustrating the solar PV (4) covered roof-like structure (2)(3) embodied in this invention and the various optional elements employed in conducting electrical power such as catenary (6) and messenger line (7), third conductor rail (11), or parallel power bus (13) to train vehicles for developing traction power.

FIG. 2a shows another end view or cross-section view of one canopy module (1-1) illustrating one of several possible variations within principles of the solar PV (4) covered roof-like structure (2)(3) embodied in this invention and the various optional elements employed in conducting electrical power such as catenary (6) and messenger line (7), third conductor rail (11), or parallel power bus (13) to train vehicles for developing traction power.

FIG. 3 shows a side view of electric powered rail vehicles (10) under joined (21) solar PV power generating canopy modules (1-1 of FIG. 1) to include overhead power distribution line or messenger line (7) and power pickup mechanism (8)(9).

FIG. 4 illustrates the basic flow of electrical power from the embodied solar PV power generating panels (4) of the canopy module(s) (1-1 of FIG. 1) through inverter(s) (17) and other electrical components (s) (18) to local and or regional power grid (19) (20) and back from said grid through other electrical components (18) for conduction to rail vehicle(s) (7) or (11) or (13) to provide traction power for said vehicle(s) (10). For the purpose of illustration, actual conducive circuitry is simplified to show only the relative functional placement of elements in the system.

### DETAILED DESCRIPTION OF THE INVENTION

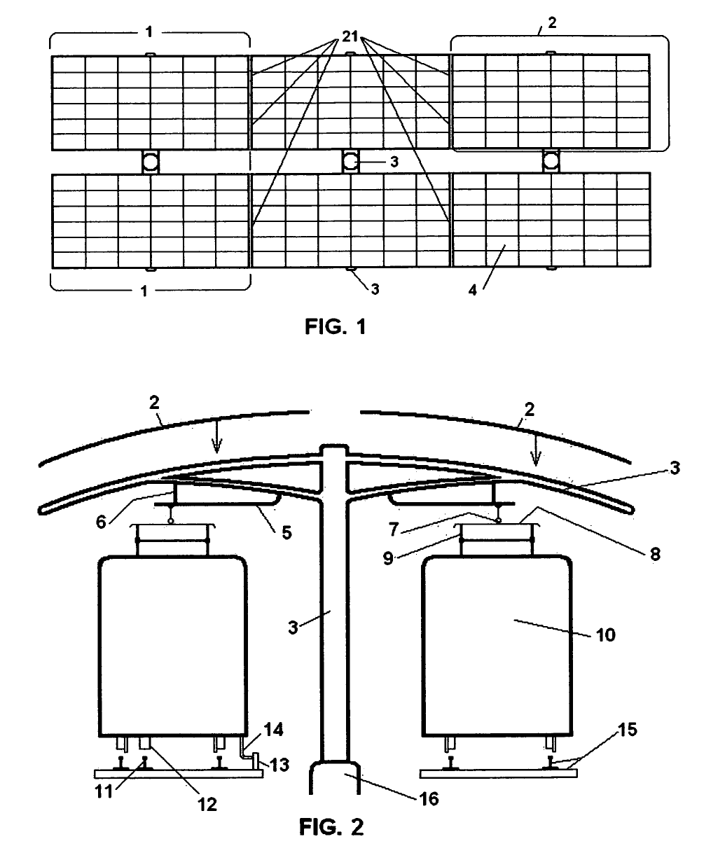

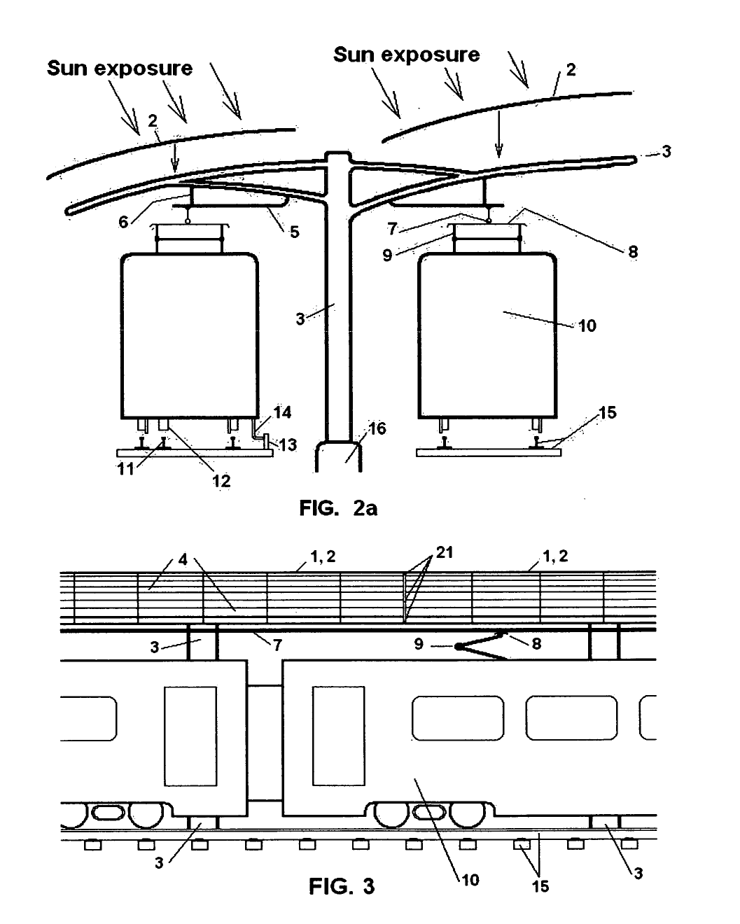

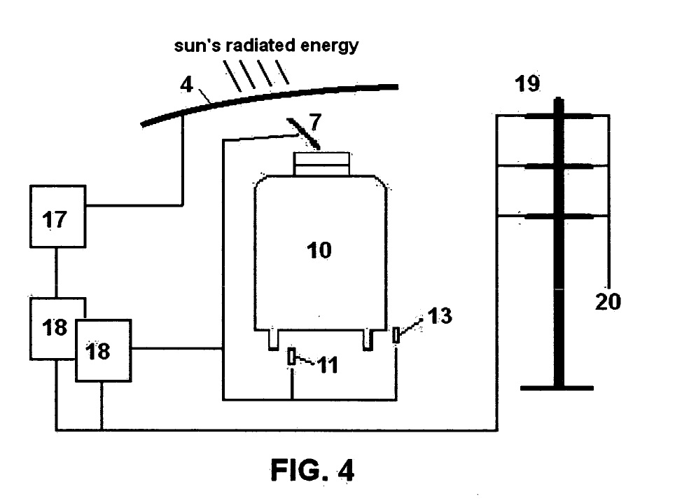

Although the following descriptions FIG. 1 through 4 contain some specific details for the purpose of illustration, anyone of ordinary skill in the art and the field of solar PV canopy and structural design, and the field of power electrical engineering will appreciate that variations and alterations to the following presentations herein are within the scope of this invention.

Accordingly, the embodiments of the invention described below are set forth without any loss of generality to, and without imposing limitations upon, the claimed invention.

Embodiments of the present invention relate to the integration of solar photovoltaic technology and products derived there from with the available use of air rights (space above) a rail operator's tracks and owned right-of-way, and doing so concurrently with full operation of said right-of-way for the purpose of producing carbon free electrical power.

Solar PV canopy designs are not new. Solar PV canopy designs for installation and operation over (above) in-service rail tracks and right-of-way for the purpose of developing traction power is new.

Integrating the high voltage power delivery conductor for electrified rail vehicles under a plurality of modular solar PV canopies and above said electric vehicles is new.

By calculating the annual electrical power consumption of a rail line (or system) in kilowatt hours (kWh) per year; and dividing that by the calculated or projected annual kWh power output of one kilometer or mile of selected solar PV canopy, a rail owner, operator or oversight agency can calculate the surface area or length or some plurality of solar PV canopy modules (1-1) required to generate carbon free renewable electrical power (kWh/year) equivalent to that consumed in an average year of operation and thus determine the canopy surface area required to make that rail system Carbon Neutral.

By calculating the projected total annual kWh power output of some combined total length of or some plurality of solar PV canopy modules, and dividing that by the annual electrical power consumption of subject rail line (or system) in kilowatt hours (kWh) per year, said owner, operator or oversight agency can calculate the extent to which that system is Carbon Neutral by virtue of the installed solar PV canopy modules.

What is claimed is:

1) A method of generating high potential electrical energy for electric powered rail vehicle traction power comprising a plurality of solar PV (4) covered (2) roof-like structures (3) said herein canopy modules (1-1), in alignment with and above a tie-and-rail vehicle guide track system (15) or right of way.

2) The plurality of solar PV covered canopy modules of claim 1, wherein said canopy modules are substantially similar in size, shape, design, composition and electrical generating capability.

3) The plurality of solar PV covered canopy modules of claim 1, wherein said canopy modules of substantially of the same size, shape, design, composition may very as required to best fit the needs, geometry or variations of and within said rail system.

4) The plurality of solar PV covered canopy modules of claim 1, wherein said canopy modules are covered with solar photovoltaic panels or materials (4) for the purpose of generating electric power.

5) The plurality of solar photovoltaic panels (4) of claim 4, wherein said panels are of substantially like size, shape, mass and electrical generating capability.

6) The plurality of solar photovoltaic panels (4) of claim 4, wherein said panels may number from 1 to N (any) as determined by size, weight, nature, design, technology and power generating capability.

7) The plurality of solar photovoltaic panels (4) of claim 4, wherein said panels or materials may comprise materials, technologies and methods of manufacturing such as but not limited to thin-film or crystalline, transparent, semi-transparent, or opaque, flexible or not flexible substrates or membranes.

8) The plurality of solar PV covered canopy modules of claim 1, wherein the support structure (3) of said module(s) (1-1) are typically supported by, but not limited to, a single vertical support member substantially positioned within the center of mass when viewed from above.

9) The vertical support member of claim 8, wherein said vertical support member or members are substantially of the same design, materials, size and construction.

10) The plurality of solar PV covered canopy modules of claim 1, wherein the support structure(s) (3) are designed to accept, affix and secure solar photovoltaic panels elements, substrates or membrane embodied in claim 4.

11) The plurality of solar PV covered canopy modules of claim 1, wherein the upper portion of support structure(s) (3) may contain attachment apparatus, mechanism(s) or feature(s) s to locate and secure mounting connection(s) for catenary (6) supporting and securing messenger line for overhead high voltage electrical delivery to power conductor device (8) and (9) to provide electrical traction power for rail vehicle(s).

12) The overhead high voltage power delivery conductor of claim 11, wherein said conductor comprises wire (7) and Catenary support system under a method of controlled tension.

13) The plurality of solar PV covered canopy modules of claim 1, wherein said canopy modules contain features to connect or join (21) one canopy module to other identical or similar canopy modules in an end-to-end manor in alignment with and above said tie and rail vehicle guide system.

14) The plurality of solar PV covered canopy modules (1-1) of claim 1, wherein said modules may be joined (21) in any number of pluralities to form continuous and varied lengths of electrical power generating covered structures here in stated modules.

15) The connection features of claim 14, wherein said features shall be for the purpose of facilitating one or more of the following:
a) module-to-module geometrical alignment,
b) secure mechanical attachment,
c) seismic and wind effect stabilization,
d) electrical conduction,
e) ground potential compliance
f) and other purpose(s) as may be required.

16) The plurality of varied lengths of joined (21) solar PV covered canopy modules (1-1) of claim 14, wherein said varied lengths may be separated by open or unconnected spaces between sets or joined (21) canopy modules for reason of:
a) grade crossing(s) or separation(s)
b) overhead crossing(s), obstruction(s) to sunlight exposure, overhead high voltage power delivery phase matching,
c) overhead high voltage power delivery system tensioning mechanism(s),
d) designed breaks or openings for disconnecting high voltage overhead power delivery line for inspection,
e) maintenance and repair,
f) and other as may be required or appropriate.

17) The plurality of varied lengths of joined (21) solar PV covered canopy modules (1-1) of claim 16, wherein the pluralities of connected or joined canopy modules may generate electrical power individually or collectively in any desired manor.

18) The DC electrical power generated by the plurality of canopy modules in claim 1, wherein said DC power is aggregated, conducted and inverted to produce phase matched AC voltage compatible with the local and or regional electrical power grid supply connected thereto.

19) The AC voltage of claim 18, wherein said AC electrical power is conducted to the local and or regional grid supply.

20) The local and or regional grid or electrical power grid operator of claim 19, wherein that grid operator supplies back to the solar PV power generating rail operator a substantially uninterruptible supply of AC electrical power for operating said rail system.
